(19) United States
(12) Patent Application Publication
(10) Pub. No.: US 2018/0033224 A1
(43) Pub. Date: Feb. 1, 2018

(54) ALTERNATING CURRENT (AC) LOAD PRE-CHARGE PROTECTION

(71) Applicant: Lear Corporation, Southfield, MI (US)

(72) Inventors: Krzysztof KLESYK, Novi, MI (US); Raef AIDIBI, Dearborn Heights, MI (US)

(21) Appl. No.: 15/664,643

(22) Filed: Jul. 31, 2017

Related U.S. Application Data
(60) Provisional application No. 62/369,645, filed on Aug. 1, 2016.

(51) Int. Cl. G07C 5/08; H03K 5/26; H02H 7/20; H02M 7/537

(52) U.S. Cl. CPC G07C 5/0808; H02M 7/537; H03K 5/26; H02H 7/20

(57) ABSTRACT

In at least one embodiment, a vehicle apparatus including a power conversion device is provided. The power conversion device is further configured to receive a direct current (DC) output voltage and invert the DC output voltage into an alternating current (AC) based signal to drive one or more AC loads in a vehicle. The power conversion device is further configured to measure the DC output voltage during a pre-charge operation and to provide a diagnostic threshold during the pre-charge operation based on the measured DC output voltage. The power conversion device is further configured to determine a plurality of accumulated values during the pre-charge operation, each accumulated value is indicative of a measured current across a resistive element. The power conversion device is further configured to compare the plurality of accumulated values to the diagnostic threshold during the pre-charge operation.

### CROSS-REFERENCE TO RELATED APPLICATIONS

This application claims the benefit of U.S. provisional application Ser. No. 62/369,645 filed on Aug. 1, 2016, the disclosure of which is hereby incorporated in its entirety by reference herein.

### TECHNICAL FIELD

Aspects disclosed herein generally relate to an AC load pre-charge protection circuit and method. These aspects and others will be discussed in more detail herein.

### BACKGROUND

U.S. Publication No. 2016/0152156 to Pritelli et al. discloses an electronic device for controlling the electric charge of a load electrically supplied by a battery pack. The electronic device includes: a support; a control module integrated in the support; an electric pre-charging circuit of the load controlled by the control module; and an electric active discharge circuit of the load controlled by the control module. The electric pre-charging circuit comprises at least one first solid-state switch and is integrated on the support. The electric active discharge circuit includes at least one second solid-state switch and is integrated on the support. The first solid-state switch and the second solid-state switch can be configured to work either as a switch or as a variable resistor.

### SUMMARY

In at least one embodiment, a vehicle apparatus including a power conversion device is provided. The power conversion device is further configured to receive a direct current (DC) output voltage and invert the DC output voltage into an alternating current (AC) based signal to drive one or more AC loads in a vehicle. The power conversion device is further configured to measure the DC output voltage during a pre-charge operation and to provide a diagnostic threshold during the pre-charge operation based on the measured DC output voltage. The power conversion device is further configured to determine a plurality of accumulated values during the pre-charge operation, each accumulated value is indicative of a measured current across a resistive element. The power conversion device is further configured to compare the plurality of accumulated values to the diagnostic threshold during the pre-charge operation.

In at least another embodiment, a vehicle apparatus including a power conversion device is provided. The power conversion device is configured to invert a direct current (DC) output voltage into an alternating current (AC) based signal to drive one or more AC loads in a vehicle and to measure the DC output voltage during a pre-charge operation. The power conversion device is further configured to provide a diagnostic threshold during the pre-charge operation based on the measured DC output voltage and to measure a current across a resistive element. The power conversion device is further configured to determine a plurality of accumulated values during the pre-charge operation and each accumulated value is indicative of a measured current across the resistive element. The power conversion device is further configured to compare the plurality of accumulated values to the diagnostic threshold during the pre-charge operation.

In at least another embodiment, a method for pre-charge protection is provided. The method includes receiving a direct current (DC) output voltage at a power conversion device and inverting the DC output voltage at the power conversion device into an alternating current (AC) based signal to drive one or more AC loads in a vehicle. The method further includes measuring the DC output voltage during a pre-charge operation and providing a diagnostic threshold during the pre-charge operation based on the measured DC output voltage. The method further includes determining a plurality of accumulated values during the pre-charge operation, each accumulated value being indicative of a measured current across a resistive element and comparing the plurality of accumulated values to the diagnostic threshold during the pre-charge operation.

### BRIEF DESCRIPTION OF THE DRAWINGS

The embodiments of the present disclosure are pointed out with particularity in the appended claims. However, other features of the various embodiments will become more apparent and will be best understood by referring to the following detailed description in conjunction with the accompany drawings in which:

FIG. 1 depicts a system that provides AC load pre-charge protection in accordance to one embodiment;

FIG. 2 depicts various waveforms for current, voltage, a diagnostic threshold, and a plurality of accumulated values in accordance to one embodiment;

FIG. 3 depicts a method for monitoring current (or power) based on a measured bulk voltage that is provided to the system in accordance to one embodiment;

FIG. 4 depicts a waveform for a measured current and a measured bulk voltage (or measured voltage of the capacitance load) of the inverter in accordance to one embodiment; and

FIG. 5 depicts various pulse impulse power characteristics for various resistors.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

The embodiments of the present disclosure generally provide for a plurality of circuits or other electrical devices. All references to the circuits and other electrical devices and the functionality provided by each are not intended to be limited to encompassing only what is illustrated and described herein. While particular labels may be assigned to the various circuits or other electrical devices disclosed, such labels are not intended to limit the scope of operation for the circuits and the other electrical devices. Such circuits and other electrical devices may be combined with each other and/or separated in any manner based on the particular type of electrical implementation that is desired. It is recognized that any circuit or other electrical device disclosed herein may include any number of microcontrollers, graphics processor unit (GPU), integrated circuits, memory devices (e.g., FLASH, random access memory (RAM), read only memory (ROM), electrically programmable read only memory (EPROM), electrically erasable programmable read only memory (EEPROM), or other suitable variants thereof) and software which co-act with one another to perform operation(s) disclosed herein. In addition, any one or more of the electrical devices may be configured to execute a computer-program that is embodied in a non-transitory computer readable medium that is programmed to perform any number of the functions as disclosed.

It is generally known to provide a pre-charge circuit in a vehicle. Generally, such circuits utilize a high surge power rated resistor to withstand the amount of power that is dissipated across the resistor during the pre-charge operation. Such a resistor generally adds cost and may affect the pre-charge time due to the power dissipation properties of the resistor. Aspects disclosed herein may eliminate the need for utilizing the high surge power rated resistor to mitigate such cost and to avoid adversely affecting the pre-charge time.

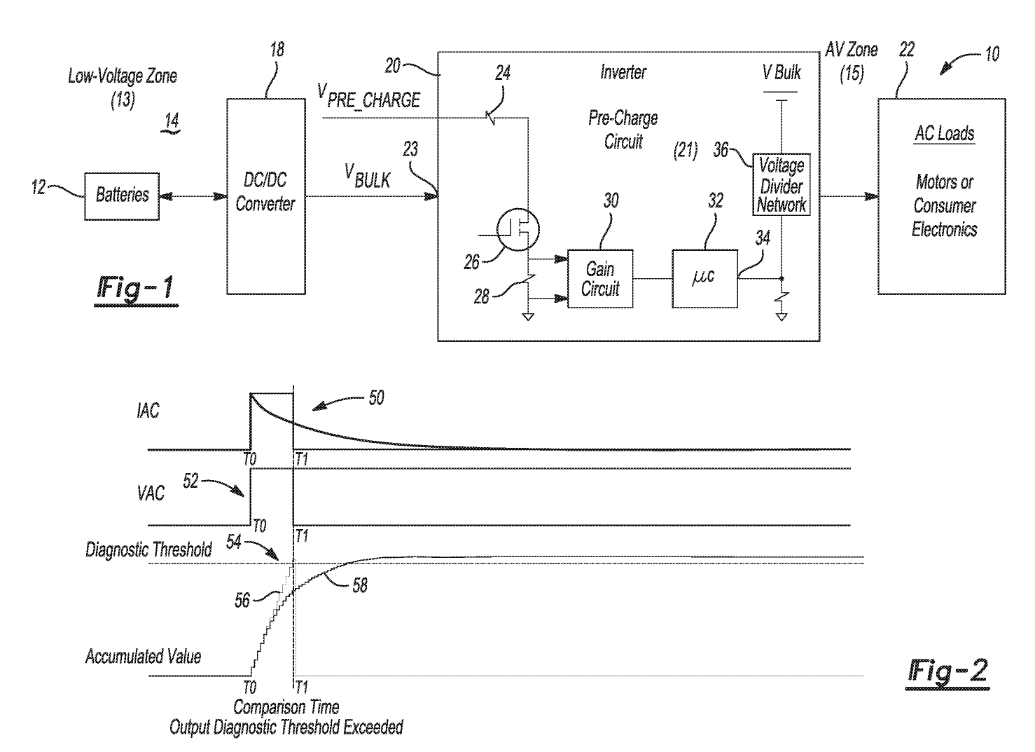

FIG. 1 depicts a vehicle apparatus 10 that provides AC load pre-charge protection in accordance to one embodiment. The vehicle apparatus 10 generally includes one or more batteries 12 for powering a vehicle 14. The one or more batteries 12 is generally located in a low voltage zone 13 for powering any number of devices (not shown) within the low voltage zone that operate within the vehicle 14. A DC/DC converter 18 is operatively coupled to the one or more batteries 12 for receiving a low voltage output therefrom. An inverter 20 (e.g., a power conversion device in a high voltage zone) is operatively coupled to the DC/DC converter 18 to receive a boosted voltage therefrom.

The inverter 20 generates an AC output for powering various AC loads 22 such as motors, consumer electronic devices, etc. The inverter 20 includes a pre-charge circuit 21 to limit inrush current and to thereby prevent any number of capacitors (not shown) from being damaged by the inrush current. A pre-charge operation is generally performed when initially connecting a voltage source to a load with a capacitive load.

The pre-charge circuit 21 generally includes a pre-charge resistor 24 (e.g., a resistive element), a switching device 26 (e.g., MOSFET), a resistor 28 (or current sensing resistor 28), a gain circuit 30, and a microprocessor 32. A pre-charge voltage (e.g., V ₚᵣₑ_{_}_{charge}) is provided to the pre-charge resistor 24 and to the switching device 26 during the pre-charge operation. The current sensing resistor 28 generates current which is indicative of the current flowing through the pre-charge resistor 24 when the voltage is applied to the pre-charge resistor 24 during the pre-charge operation. The gain circuit 30 amplifies the current across the pre-charge resistor 24. The microprocessor 32 receives the current from the gain circuit 30 to determine the current that flows across the pre-charge resistor 24. In one example, the pre-charge resistor 24 may be 51 ohms. It is recognized that the pre-charge resistor 24 may be any other suitable value.

The pre-charge circuit 21 includes an input 23 for receiving a voltage indicative of a bulk voltage from the DC/DC converter 18 during the pre-charge operation. In general, the inverter 20 generates the AC output in response to the bulk voltage (or DC output voltage) from the DC/DC converter 18. The bulk voltage range for a 120 V system may be 100 to 182 V and the bulk voltage range for a 240 V system may be 200 to 364 V. A voltage divider network 36 steps down the bulk voltage into a voltage that is suitable by the microprocessor 32 to determine (or measure) the bulk voltage output from the DC/DC converter 18. The voltage divider network 36 scales the bulk voltage down from over 100 V into a voltage somewhere within a range of, for example, 0 to 5 volts. Once in this range, an analog to digital converter (ADC) (not shown) within the microprocessor 32 converts the analog version of the scaled down voltage to digital counts. The microprocessor 32 then executes software to obtain values corresponding to the bulk voltage.

In general, the pre-charge circuit 21 is configured to store values (e.g. via memory either external or internal to the microprocessor 32) corresponding to the measured bulk voltage output by the DC/DC converter 18 and to store a corresponding diagnostic threshold based on measured bulk voltage. The pre-charge circuit 21 compares either the measured current across the current sensing resistor 28 to the diagnostic threshold or compares a calculated power (based on the measured current and the resistance of the current sensing resistor 28) to the diagnostic threshold. If the measured current exceeds or calculated power exceeds the diagnostic threshold, then the pre-charge circuit 21 may deactivate the pre-charge operation.

For example, the microprocessor 32 may measure a plurality of accumulated values (i.e., current or power) within a time interval (e.g., or between a first time set point T₀ and a second time set point T₁) and compares the latest accumulated measured value after a predetermined number of counts has been reached to the diagnostic threshold. The microprocessor 32 includes a timer (not shown) that is initiated once the pre-charge operation has started. The timer generates a reoccurring count that increases over time within the time interval. If the latest accumulated measured value has exceeded the diagnostic threshold, then the pre-charge circuit 21 may deactivate the pre-charge operation. If the latest accumulated measured value has not exceeded the diagnostic threshold, then the microprocessor 32 allows the pre-charge operation to continue.

FIG. 2 depicts a waveform for current, voltage, the diagnostic threshold, and accumulated values in accordance to one embodiment. Waveform 50 generally corresponds to the amount of current flowing through the pre-charge resistor 24 during the pre-charge operation. The first time set point T₀ corresponds to a start point of the pre-charge operation and the second time set point T₁ corresponds to an end-point of the pre-charge operation. The first time set point T₀, the second time set point T₁ and corresponding time set points between the first time set point T₀ and the second time set point T₁ form a pre-charge time interval. Waveform 52 generally corresponds to the measured bulk voltage within the inverter 20. Waveform 54 generally corresponds to a diagnostic threshold that may vary based on the bulk voltage output by the DC/DC converter 18. A corresponding power threshold value or current threshold value is stored as the diagnostic threshold based on the measured bulk voltage. It is recognized that there can be any number of diagnostic thresholds utilized by the microprocessor 32 where each of the diagnostic thresholds correspond to a particular measured bulk voltage.

Waveform 56 illustrates a plurality of accumulated power measurements in which the measurements are detected to exceed the diagnostic threshold 54 before the second time set point T₀ has been reached. Waveform 58 illustrates a plurality of accumulated values (or accumulated power values) that do not exceed the diagnostic threshold 54. As can be seen, waveform 58 crosses the diagnostic threshold 54 after the pre-charge operation has occurred.

The microprocessor 32 may accumulate the power (or current measurements) (or accumulated values) for each count at, for example, 133 μs or other suitable value. In this example, if after 14 samples (or other suitable time sample value), the accumulated value exceeds the diagnostic threshold (e.g., see waveform 56) at some time between the first time set point T₀ and the second time set point T₁ (or within the pre-charge time interval), then the microprocessor 32 terminates the pre-charge operation to preserve the overall integrity of the pre-charge resistor 24. If on the other hand after 14 samples (or other suitable sample value), the accumulated value does not exceed the diagnostic threshold (e.g., see waveform 58) at some time between the first time set point T₀ and the second time set point T₁ (or within the pre-charge time interval), then the microprocessor 32 allows the pre-charge operation to continue. Thus, it can be seen that by accumulating the measurements at small sample sizes, the pre-charge circuit 21 may characterize the amount of current flowing through the pre-charge resistor 24 at a faster rate and quickly disable the pre-charge operation sooner in order to preserve the integrity of the pre-charge resistor 24. Further, this condition negates the use of high surge power resistors that may be used as a pre-charge resistor and reduces the overall cost for the pre-charge resistor.

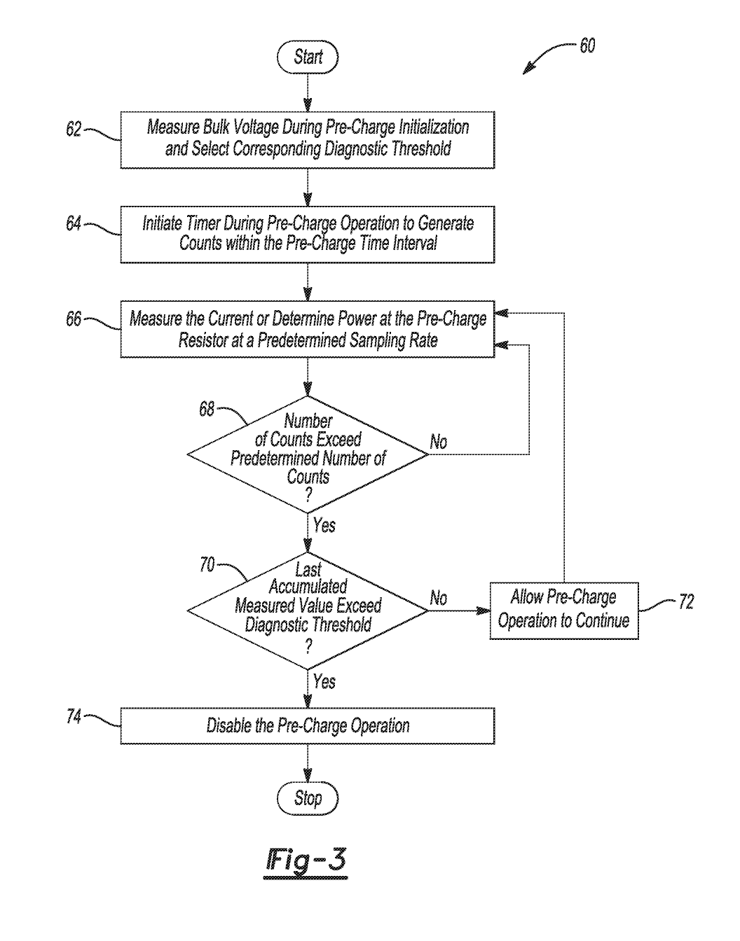

FIG. 3 generally depicts an example method 60 that may be performed by the microprocessor 32 (or other suitable variant) for determining whether the measured current or calculated power measurement exceeds the diagnostic threshold.

In operation 62, the microprocessor 32 determines the bulk voltage output by the DC/DC converter 18 during the pre-charge operation and selects the corresponding diagnostic threshold from a plurality of diagnostic thresholds based on the diagnostic threshold. The microprocessor 32 is configured to store any number of diagnostic thresholds for the measured current or power based on the bulk voltage at the inverter 20. The microprocessor 32 initiates and controls the pre-charge operation. For example, the microprocessor 32 controls the initiation and termination of the pre-charge operation.

In operation 64, the microprocessor 32 initiates the timer at the start of the pre-charge operation to generate a count and increase the count within the pre-charge time interval.

In operation 66, the microprocessor 32 measures the current or determines the power across the pre-charge resistor 24 at the pre-charge time interval at a predetermined sampling rate. The microprocessor 32 is configured to measure a plurality of accumulated measurement values (i.e., current or power) across the pre-charge resistor 24. For example, the microprocessor 32 measures the accumulated measurement values across the current sensing resistor 28 which provide a representation of the current or power at the pre-charge resistor 24.

In operation 68, the microprocessor 32 determines whether the number of counts exceed a predetermined number of counts. If the microprocessor 32 determines that the number of counts has exceed the predetermined number of counts, the method 60 proceeds to operation 70. If not, then the method 60 proceeds back to operation 66.

In operation 70, the microprocessor 32 compares the latest accumulated measured value against the diagnostic threshold. If the microprocessor 32 determines that the latest accumulated measured value has not exceeded the diagnostic threshold, then the method 60 proceeds to operation 72. If the microprocessor 32 determines that the latest accumulated measured value has exceed the diagnostic threshold, then the method 60 proceeds to operation 74.

In operation 72, the microprocessor 32 allows the pre-charge operation to continue.

In operation 74, the microprocessor 32 disables the pre-charge operation.

It is recognized that the embodiments disclosed herein may (i) be implemented in, for example, a 400 W inverter, (ii) account for a capacitive load experience with an exponential delay in charge current after the switching device is turned on, (iii) provide current that is sensed through a current sense circuit or amplifier circuit, (iv) provide sampling at 133 μs or other suitable value and at an initial current maximum of 170/510 Ohm resistor that yields 3.13 A (for example) and that the current should decay to less than 2.5 A (for example) in 2 ms; (iv) provide measurements that are accumulated as power V.bulk*I; (v) terminate the pre-charge operation and enable an inverter bridge once accumulated power (or current) exceeds predetermined thresholds, and (vi) provide similar maximum power diagnostics that can be used for normal bridge operation for a quick acting shut down.

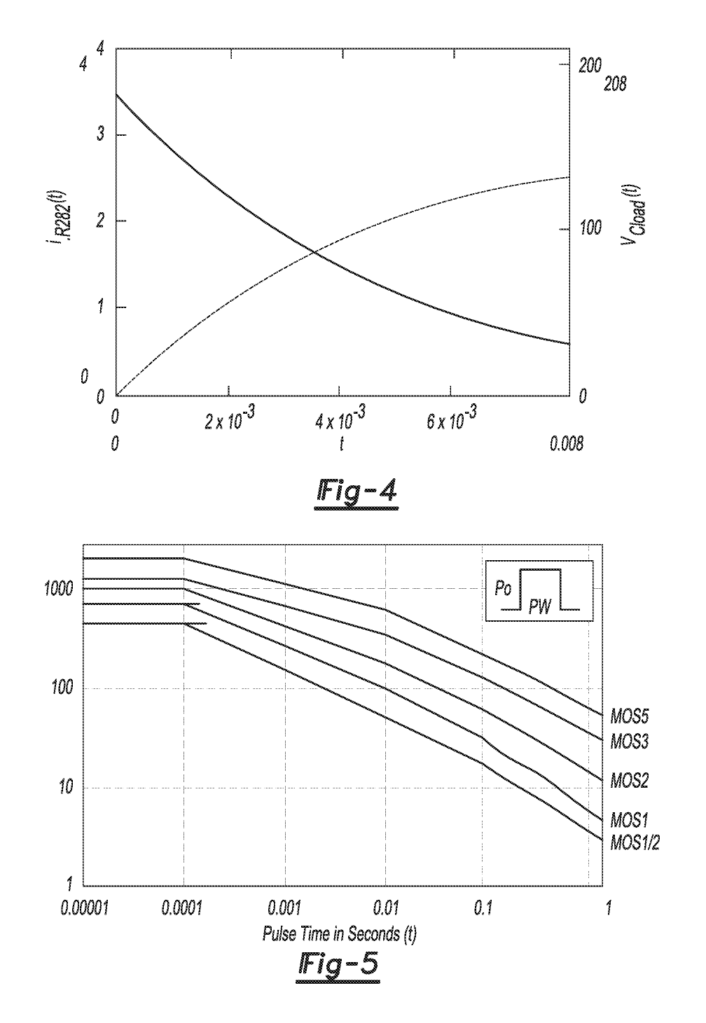

FIG. 4 depicts a waveform for the measured current and the measured bulk voltage (or measured voltage of the capacitance load) of the inverter 20 in accordance to one embodiment. FIG. 5 depicts various pulse impulse power characteristics for various resistors. In general, during a soft start operation with a capacitive load, the pre-charge resistor 24 may dissipate a peak of 554 W with a total pulse power of 104 W over an 8 ms period. The time can be extended for larger capacitive loads to allow for greater load flexibility. The pre-charge operation can be extended for larger capacitive loads to allow for greater load flexibility. The pre-charge operation may be terminated based on output energy consumption rather than fixed by time. During shorted output conditions, the same resistor would dissipate 558 W during the same period. A lower cost pre-charge resistor 24 (e.g., MOS3) is rated for approximately 250 W for 8 ms. If the pulse is terminated at 2 ms, the MOS3 pre-charge resistor 24 may take 560 W (see FIG. 5). An output of the inverter bridge may continue with operation, since no exponential decay could also be a result of high current load. Use of the MOS3 pre-charge resistor 24 may provide a cost savings over other higher rated resistors.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. A vehicle apparatus comprising:
a power conversion device configured to:
receive a direct current (DC) output voltage;
invert the DC output voltage into an alternating current (AC) based signal to drive one or more AC loads in a vehicle;
measure the DC output voltage during a pre-charge operation;
provide a diagnostic threshold during the pre-charge operation based on the measured DC output voltage;
determine a plurality of accumulated values during the pre-charge operation, each accumulated value being indicative of a measured current across a resistive element; and
compare the plurality of accumulated values to the diagnostic threshold during the pre-charge operation.

2. The vehicle apparatus of claim 1 wherein the power conversion device is further configured to compare the plurality of accumulated values to the diagnostic threshold within a pre-charge time interval.

3. The vehicle apparatus of claim 2 wherein the power conversion device is further configured to deactivate the pre-charge operation to preserve the resistive element in response to any one of the plurality of accumulated values exceeding the diagnostic threshold during the pre-charge time interval.

4. The vehicle apparatus of claim 2 wherein the power conversion device is further configured to enable the pre-charge operation to continue in response to any one of the plurality of accumulated values being below the diagnostic threshold.

5. The vehicle apparatus of claim 2 wherein the power conversion device is further configured to measure the current across the resistive element at a predetermined sampling rate within the pre-charge time interval to determine the plurality of accumulated values.

6. The vehicle apparatus of claim 1 wherein the power conversion device includes memory to store a plurality of diagnostic thresholds, and wherein each diagnostic threshold corresponds to a particular measured DC output voltage during the pre-charge operation.

7. The vehicle apparatus of claim 6 wherein the power conversion device includes a microprocessor configured to select a corresponding diagnostic threshold from the plurality of diagnostic thresholds based on the particular measured DC output voltage.

8. A vehicle apparatus comprising:
a power conversion device configured to:
invert a direct current (DC) output voltage into an alternating current (AC) based signal to drive one or more AC loads in a vehicle;
measure the DC output voltage during a pre-charge operation;
provide a diagnostic threshold during the pre-charge operation based on the measured DC output voltage;
measure a current across a resistive element;
determine a plurality of accumulated values during the pre-charge operation, each accumulated value being indicative of a measured current across the resistive element; and
compare the plurality of accumulated values to the diagnostic threshold during the pre-charge operation.

9. The vehicle apparatus of claim 8 wherein the power conversion device is further configured to compare the plurality of accumulated values to the diagnostic threshold within a pre-charge time interval.

10. The vehicle apparatus of claim 9 wherein the power conversion device is further configured to deactivate the pre-charge operation to preserve the resistive element in response to any one of the plurality of accumulated values exceeding the diagnostic threshold during the pre-charge time interval.

11. The vehicle apparatus of claim 9 wherein the power conversion device is further configured to enable the pre-charge operation to continue in response to any one of the plurality of accumulated values being below the diagnostic threshold.

12. The vehicle apparatus of claim 9 wherein the power conversion device is further configured to measure the current across the resistive element at a predetermined sampling rate within the pre-charge time interval to determine the plurality of accumulated values.

13. The vehicle apparatus of claim 8 wherein the power conversion device includes memory to store a plurality of diagnostic thresholds, and wherein each diagnostic threshold corresponds to a particular measured DC output voltage during the pre-charge operation.

14. The vehicle apparatus of claim 13 wherein the power conversion device includes a microprocessor configured to select a corresponding diagnostic threshold from the plurality of diagnostic thresholds based on the particular measured DC output voltage.

15. A method comprising:
receiving a direct current (DC) output voltage at a power conversion device;
inverting the DC output voltage at the power conversion device into an alternating current (AC) based signal to drive one or more AC loads in a vehicle;
measuring the DC output voltage during a pre-charge operation;
providing a diagnostic threshold during the pre-charge operation based on the measured DC output voltage;
determining a plurality of accumulated values during the pre-charge operation, each accumulated value being indicative of a measured current across a resistive element; and
comparing the plurality of accumulated values to the diagnostic threshold during the pre-charge operation.

16. The method of claim 15 wherein comparing the plurality of accumulated values to the diagnostic threshold further includes comparing the plurality of accumulated values to the diagnostic threshold within a pre-charge time interval.

17. The method of claim 16 further comprising deactivating the pre-charge operation to preserve the resistive element in response to any one of the plurality of accumulated values exceeding the diagnostic threshold during the pre-charge time interval.

18. The method of claim 16 further comprising enabling the pre-charge operation to continue in response to any one of the plurality of accumulated values being below the diagnostic threshold.

19. The method of claim 16 further comprising measuring the current across the resistive element at a predetermined sampling rate within the pre-charge time interval to determine the plurality of accumulated values.

20. The method of claim 15 further comprising storing a plurality of diagnostic thresholds in memory of the power conversion device, and wherein each diagnostic threshold corresponds to a particular measured DC output voltage during the pre-charge operation.
